(19) United States
(12) Patent Application Publication
(10) Pub. No.: US 2014/0146471 A1
(43) Pub. Date: May 29, 2014

(54) AIR DUCT AND ELECTRONIC DEVICE WITH THE SAME

(71) Applicants: Hong Fu Jin Precision Industry (ShenZhen) Co., Ltd., (US); Hon Hai Precision Industry Co., Ltd., (US)

(72) Inventor: LEI LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/717,716

(22) Filed: Dec. 18, 2012

(30) Foreign Application Priority Data
Nov. 28, 2012 (CN) 201210493516.5

(51) Int. Cl. F24F 7/04; H05K 7/20

(52) U.S. Cl. CPC F24F 7/04; H05K 7/20145
USPC 361/695; 454/284

(57) ABSTRACT

An air duct includes a base body, a pivoting member, and a fastener including a pole. The base body includes a base portion and two extension portions. The base portion includes a top plate and two side plates extending down from opposite sides of the top plate. The extension portions extend forward from front ends of the side plates. The pivoting member includes a top cover and two side covers extending down from opposite sides of the top cover. The side covers respectively abut the extension portions. A rear end of the pivoting member is rotatably connected to the base portion. When the pivoting member is rotated to one of different positions, the pole extends through one of the side covers and the corresponding extension portion to fasten the pivoting member to the base body.

### BACKGROUND

1. Technical Field

The present disclosure relates to an electronic device with an air duct.

2. Description of Related Art

An air duct is often mounted in a server to guide airflow. Guided by the air duct, different areas of the server generally obtain constant airflow. If the configuration of the server varies, for example, a low heat-generating expansion card is replaced by a high heat-generating expansion card such as a graphic processing unit, the airflow that the graphic processing unit obtains may be not enough, and needs to be adjusted.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of an electronic device, wherein the electronic device includes an air duct.

FIG. 2 is an exploded, isometric view of the air duct of FIG. 1, wherein the air duct includes two fasteners.

FIG. 3 is an enlarged view of one of the fasteners of FIG. 2.

FIGS. 4 and 5 are similar to FIG. 1, but showing different states of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

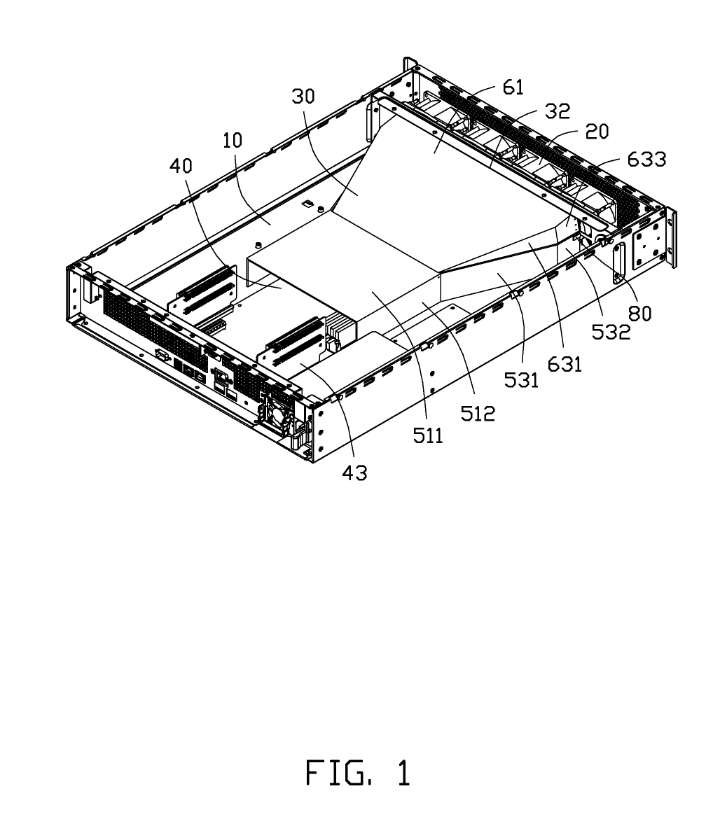

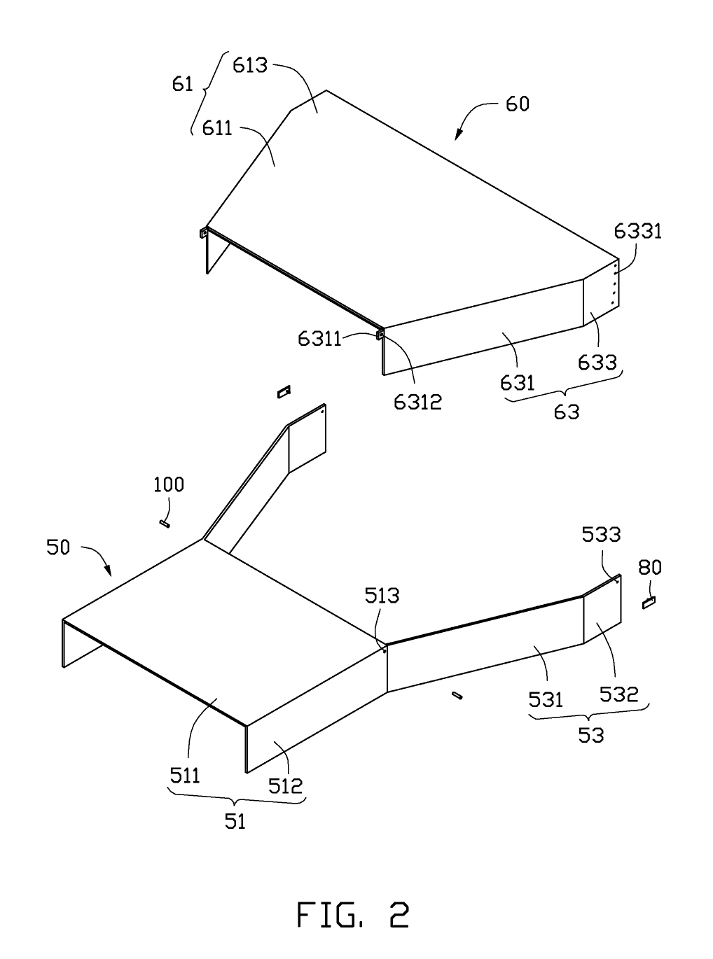

FIGS. 1 and 2 show an exemplary embodiment of an electronic device. The electronic device includes a bottom plate 10, a row of fans 20 fastened to the bottom plate 10, an air duct 30 located behind the fans 20, and a circuit board 40 fastened to the bottom plate 10 and located behind the fans 20. The air duct 30 includes a base body 50, a pivoting member 60, and two fasteners 80.

The base body 50 includes a base portion 51 and two extension portions 53. The base portion 51 includes a top plate 511 and two side plates 512 extending down from opposite sides of the top plate 511 in a substantially perpendicular manner. Each extension portion 53 includes a connection plate 531 slantingly extending forward and outward from a front end of the corresponding side plate 512, and an end plate 532 extending forward from a front end of the connection plate 531. A through hole 513 is defined in the front end of each side plate 512, near a top of the side plate 512. A through hole 533 is defined in a front end of each end plate 532, near a top of the end plate 532.

The pivoting member 60 includes a top cover 61 and two side covers 63 extending down from opposite sides of the top cover 61. The top cover 61 includes a trapezoid-shaped rear plate 611 gradually becoming wider from rear to front, and a front plate 613 extending forward from a front side of the rear plate 611. Each side cover 63 includes a guiding plate 631 extending down from the corresponding side of the rear plate 611 in a substantially perpendicular manner, and a mounting plate 633 extending down from the corresponding side of the front plate 613 in a substantially perpendicular manner and connected to the corresponding guiding plate 631. A plurality of position holes 6331 is defined in a front end of the mounting plate 633 from top to bottom, arranged as an arc. A pivoting tab 6311 extends back from an upper portion of a rear end of the guiding plate 631. A pivot hole 6312 is defined in the pivoting tab 6311.

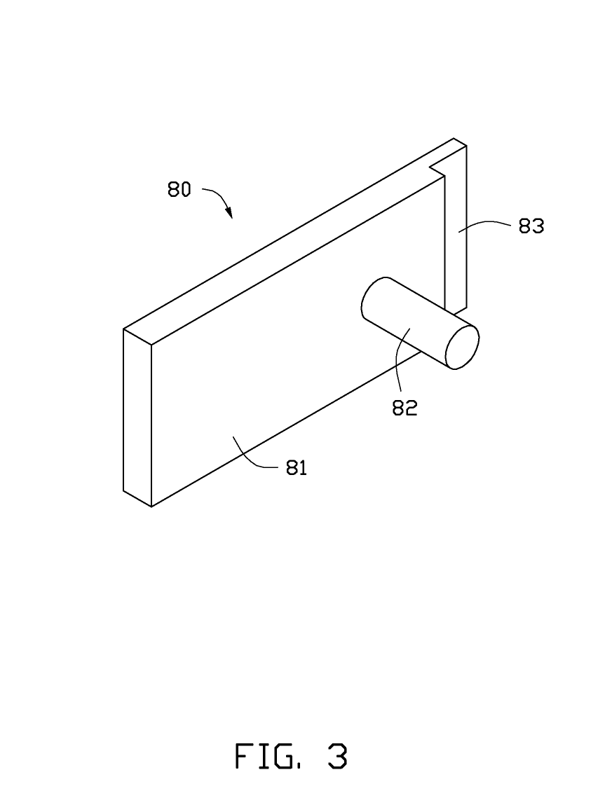

FIG. 3 shows each fastener 80 including a main body 81, a pole 82 protruding from a first side of the main body 81 and near a front end of the main body 81, and an operation portion 83 extending from the front end of the main body 81 and near a second side of the main body 81 opposite to the first side.

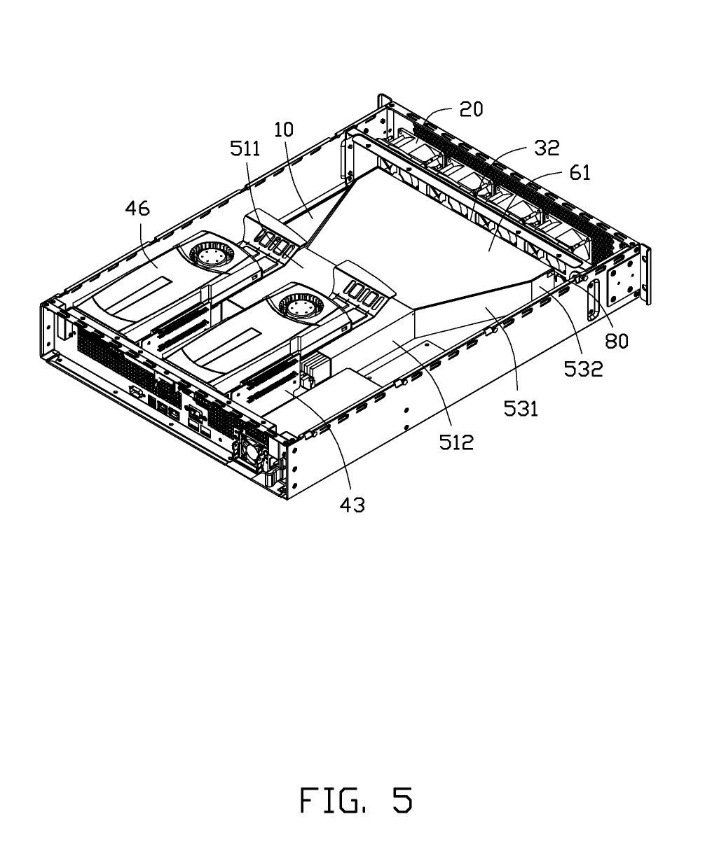

FIG. 5 shows the assembly of the air duct 30. The pivoting member 60 is moved toward the base portion 51 between the extension portions 53, until the pivot holes 6312 are aligned with the through holes 513 respectively. The mounting plates 633 respectively abut inner sides of the end plates 532, and the guiding plates 631 respectively abut inner sides of the connection plates 531. Two pins 100 extend through the through holes 513 and the pivot holes 6312, to rotatably connect the pivoting member 60 to the base body 50. The rear end of each fastener 80 is attached to an outer side of the corresponding end plate 532, and the pole 82 is operable to extend through the corresponding through hole 533. The pivoting member 60 is rotated, to allow the top outmost position hole 6331 of each mounting plate 633 to align with the through hole 533 of the corresponding end plate 532, and the top cover 61 substantially aligns with the top plate 511. The poles 82 extend through the through holes 533 and the position holes 6331, to fasten the pivoting member 60 to the base body 50.

When fastening the pivoting member 60 to a different position, the operation portions 83 are manipulated away from each other, to disengage the poles 82 from the position holes 6331 and through holes 533. The front end of the pivoting member 60 is rotated up, when different position holes 6331 of the mounting plates 633 align with the through holes 533, the poles 82 extend through the through holes 533 and the corresponding position holes 6331, to fasten the pivoting member 60 at the different position.

A bottom of the base body 50 is fastened to the bottom plate 10, to partially receive the circuit board 40 in the air duct 30. A plurality of electronic components of the circuit board 40, such as central processing units and memories, is receive in the air duct 30, two riser cards 43 of the circuit board 40 are located behind the air duct 30. The pivoting member 60 and the extension portions 53 bound an airflow inlet 32 facing and near the fans 20. When the pivoting member 60 is rotated to allow the top cover 61 to align with the top plate 511 and the pivoting member 60 is fastened to the base body 50 by the fasteners 80, the fans 20 have greater heights than the top cover 61 and the top plate 511.

Referring to FIG. 1, when none of expansion card is mounted in the riser cards 43, the pivoting member 60 is rotated up until a front edge of the top cover 61 is aligned with top sides of the fans 20, then the pivoting member 60 is fastened to the base body 50 by the fasteners 80. The airflow generated by the fans 20 mostly flows into the air duct 30 through the airflow inlet 32 and dissipates heat for the electronic components received in the air duct 30.

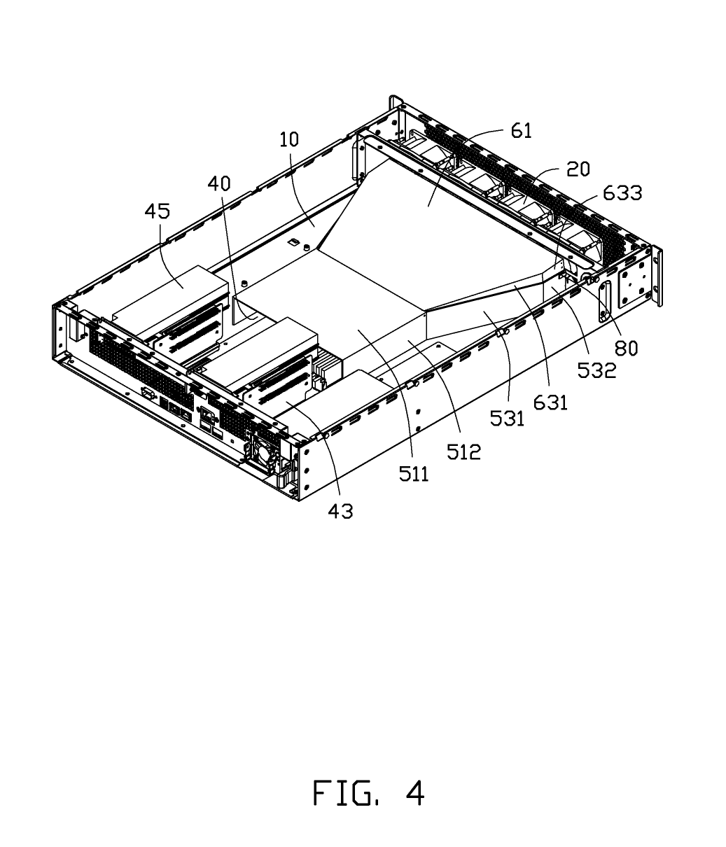

Referring to FIG. 4, when two short expansion cards 45 are mounted in the riser cards 43 and located above the base body 50, the pivoting member 60 is rotated until the front edge of the top cover 61 is located below the top sides of the fans 20 and located above the extension portions 53. A small part of the airflow generated by the fans 20 flows above the air duct 30 and dissipates heat for the expansion cards 45, the other airflow generated by the fans 20 flows into the air duct 30 through the airflow inlet 32 and dissipates heat for the electronic components received in the air duct 30.

Referring to FIG. 5, when two tall expansion cards 46, such as graphic processing units, are mounted in the riser cards 43 and located above the base body 50, the pivoting member 60 is rotated until the top cover 61 is substantially aligned with the top plate 511. A relatively large part of the airflow generated by the fans 20 flows above the air duct 30 and dissipates heat for the expansion cards 46, the other airflow generated by the fans 20 flows into the air duct 30 through the airflow inlet 32 and dissipates heat for the electronic components received in the air duct 30.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An air duct, comprising:
a base body comprising a base portion and two extension portions, the base portion comprising a top plate and two side plates extending down from opposite sides of the top plate, the extension portions extending forward from front ends of the side plates, respectively;
a pivoting member comprising a top cover and two side covers extending down from opposite sides of the top cover, the side covers respectively abutting the extension portions, a rear end of the pivoting member rotatably connected to the base portion; and
a fastener;
wherein the pivoting member rotates relative to the base body to one of plurality of positions, the fastener fastens the pivoting member to the base body at the one of the portions.

2. The air duct of claim 1, wherein each extension portion comprises a connection plate slantingly extending forward and outward from the front end of the corresponding side plate, and an end plate extending forward from a front end of the connection plate, the top cover comprises a rear plate gradually becoming wider from rear to front, and a front plate extending forward from a front side of the rear plate, two guiding plates extend down from opposite sides of the rear plate and abut inner sides of the connection plates respectively, two mounting plates extend down from opposite sides of the front plate and abut inner sides of the end plates respectively, the mounting plates are connected to front ends of the corresponding guiding plates.

3. The air duct of claim 1, wherein a pivoting tab extends back from each side cover and is rotatably connected to the corresponding side plate.

4. The air duct of claim 3, wherein each pivoting tab is near a top of the corresponding side cover, a pivot hole is defined in each pivoting tab, a through hole is defined in the front end of each side plate and near a top of the side plate, two pins respectively extend through the through holes and the pivot holes.

5. The air duct of claim 1, wherein the fastener comprises a main body and a pole, a rear end of the main body is fastened to an outer side of the corresponding extension portion, the pole protrudes from a side of the main body facing the corresponding extension portion and near a front end of the main body.

6. The air duct of claim 5, wherein a plurality of first through holes is defined in said one of the side covers from top to bottom, arranged as an arc, the corresponding extension portion defines a second through hole, the pole extends through the second through hole and one of the first through holes to fasten the pivoting member to the corresponding position.

7. The air duct of claim 5, wherein an operation portion extends forward from the front end of the main body.

8. An electronic device, comprising:
a bottom plate;
a row of fans fastened on the bottom plate;
a circuit board fastened on the bottom plate and located behind the fans; and
an air duct comprising:
a base body comprising a base portion and two extension portions, the base portion comprising a top plate and two side plates extending down from opposite sides of the top plate, the extension portions extending forward from front ends of the side plates;
a pivoting member comprising a top cover and two side covers extending down from opposite sides of the top cover, the side covers respectively abutting the extension portions, a rear end of the pivoting member rotatably connected to the base portion; and
a fastener;
wherein an airflow inlet is defined in a front end of the air duct, the circuit board is mounted with a plurality of electronic components received in the air duct and a riser card located behind the air duct, an expansion card is mounted in the riser card and higher than the base body, when the pivoting member rotates relative to the base body to one of plurality of positions, the fastener fastens the pivoting member to the base body at the one of the portions, when the pivoting member is rotated to allow a front edge of the top cover to align with top sides of the fans, most airflow from the fans flows into the air duct through the airflow inlet, when the pivoting member is rotated to allow the front edge of the top cover to be below the top sides of the fans, a part of the airflow from the fans flows into the air duct through the airflow inlet, the other airflow form the fans flows above the air duct to the expansion card.

9. The electronic device of claim 8, wherein each extension portion comprises a connection plate slantingly extending forward and outward from the front end of the corresponding side plate, and an end plate extending forward from a front end of the connection plate, the top cover comprises a rear plate gradually becoming wider from rear to front, and a front plate extending forward from a front side of the rear plate, two guiding plates extend down from opposite sides of the rear plate and abut inner sides of the connection plates respectively, two mounting plates extend down from opposite sides of the front plate and abut inner side of the end plates respectively, the mounting plates are connected to front ends of the corresponding guiding plates.

10. The electronic device of claim 8, wherein a pivoting tab extends back from each side cover and is rotatably connected to the corresponding side plate.

11. The electronic device of claim 10, wherein each pivoting tab is near a top of the corresponding side cover, a pivot hole is defined in each pivoting tab, a through hole is defined in the front end of each side plate and near a top of the side plate, two pins respectively extend through the through holes and the pivot holes.

12. The electronic device of claim 8, wherein the fastener comprises a main body and a pole, a rear end of the main body is fastened to an outer side of the corresponding extension portion, the pole protrudes from a side of the main body facing the corresponding extension portion and near a front end of the main body.

13. The electronic device of claim 12, wherein a plurality of first through holes is defined in said one of the side covers from top to bottom, arranged as an arc, the corresponding extension portion defines a second through hole, the pole extends through the second through hole and one of the first through holes to fasten the pivoting member to the corresponding position.

14. The electronic device of claim 8, wherein an operation portion extends forward from the front end of the main body.
